(19) United States
(12) Patent Application Publication
(10) Pub. No.: US 2026/0090174 A1
(43) Pub. Date: Mar. 26, 2026

(54) COVER PLATE STRUCTURE AND DISPLAY PANEL USING SAME

(71) Applicant: PlayNitride Display Co., Ltd., Zhunan Township (TW)

(72) Inventors: HIO-KUN SI, Zhunan Township (TW); Hao-Yun LAI, Zhunan Township (TW)

(73) Assignee: PlayNitride Display Co., Ltd., Zhunan Township (TW)

(21) Appl. No.: 18/989,584

(22) Filed: Dec. 20, 2024

(30) Foreign Application Priority Data
Sep. 23, 2024 (TW) 113135949

(51) Int. Cl. H10H 29/855; H10H 29/852

(52) U.S. Cl. CPC H10H 29/855; H10H 29/852

(57) ABSTRACT

A cover plate structure is provided. The cover plate structure includes a refractive layer that has a first refractive index and is divided into multiple refractive regions. There are multiple first protrusions on the first side of the refractive layer, and each refractive region corresponds to one first protrusion. The cover plate structure further includes at least one refraction structure disposed on the second side of the refractive layer and having a second refractive index. The second side is opposite the first side, and the second refractive index is different from the first refractive index.

### CROSS REFERENCE TO RELATED APPLICATIONS

This Application claims priority of Taiwan Patent Application No. 113135949, filed on Sep. 23, 2024, the entirety of which is incorporated by reference herein.

### BACKGROUND OF THE INVENTION

### Field of the Invention

The present disclosure relates in general to a cover plate structure, and in particular to a cover plate structure for enhancing the brightness of forward-emitted light, and a display panel using the same.

### Description of the Related Art

Light-emitting diode (LED) display devices are classified as active semiconductor display devices, which offer advantages such as energy efficiency, excellent contrast, and better visibility under sunlight. With the development of portable electronic devices and increasing user demands for display quality in terms of color and contrast, micro light-emitting diode (micro LED) display devices, which are fabricated by arranging LEDs in arrays, have gained increasing attention in the market.

In existing display devices, the light emission angle of display chips (e.g., micro LEDs) is relatively wide, and this can result in insufficient forward light intensity (e.g., low brightness). Improving the forward light intensity of existing display devices has become a significant issue of concern in the industry.

### BRIEF SUMMARY OF THE INVENTION

In some embodiments of the present disclosure, the cover plate structure includes a refractive layer and at least one refraction structure, which may alter the direction of light passing through, thereby increasing the overall brightness in the forward direction (e.g., the emission surface of the light-emitting chip or the normal direction facing the viewer). Additionally, the cover plate structure may effectively reduce light mixing, thus improving the overall display quality.

Some embodiments of the present disclosure include a cover plate structure. The cover plate structure includes a refractive layer that has a first refractive index and is divided into multiple refractive regions. There are multiple first protrusions on the first side of the refractive layer, and each refractive region corresponds to one first protrusion. The cover plate structure further includes at least one refraction structure disposed on the second side of the refractive layer and having a second refractive index. The second side is opposite the first side, and the second refractive index is different from the first refractive index.

Some embodiments of the present disclosure also include a display panel. The display panel includes a circuit substrate and micro light-emitting chips, the circuit substrate defines pixel regions, and the micro light-emitting chips are disposed on the circuit substrate. Each pixel region corresponds to at least one micro light-emitting chip. The display panel also includes a refractive layer that covers the pixel regions and has a first refractive index. The refractive layer is divided into refractive regions that correspond to the pixel regions, and there are first protrusions on the first side of the refractive layer that is away from the circuit substrate, and each refractive region corresponds to one first protrusion. The display panel further includes at least one refraction structure that is disposed on the second side of the refractive layer facing the circuit substrate and has a second refractive index. The second refractive index is different from the first refractive index.

### BRIEF DESCRIPTION OF THE DRAWINGS

Aspects of the embodiments of the present disclosure can be understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a partial cross-sectional view illustrating a display panel according to some embodiments of the present disclosure.

FIG. 2 to FIG. 5 are partial cross-sectional views respectively illustrating the display panels according to some other embodiments of the present disclosure.

FIG. 6A to FIG. 6H are partial cross-sectional views illustrating the method of forming the display panel at various stages according to some embodiments of the present disclosure.

FIG. 7A to FIG. 7D are partial cross-sectional views illustrating the cover plate structure according to some embodiments of the present disclosure.

FIG. 8A, FIG. 9A, FIG. 10A, and FIG. 11A are partial cross-sectional views illustrating the cover plate structure according to some other embodiments of the present disclosure.

FIG. 8B, FIG. 9B, FIG. 10B, and FIG. 11B are partial top views illustrating the cover plate structure CP according to some other embodiments of the present disclosure.

### DETAILED DESCRIPTION OF THE INVENTION

The following disclosure provides many different embodiments, or examples, for implementing different features of the subject matter provided. Specific examples of components and arrangements are described below to simplify the present disclosure. These are, of course, merely examples and are not intended to be limiting. For example, a first feature is formed on a second feature in the description that follows may include embodiments in which the first feature and second feature are formed in direct contact, and may also include embodiments in which additional features may be formed between the first feature and second feature, so that the first feature and second feature may not be in direct contact.

It should be understood that additional steps may be implemented before, during, or after the illustrated methods, and some steps might be replaced or omitted in other embodiments of the illustrated methods.

Furthermore, spatially relative terms, such as “beneath,” “below,” “lower,” “on,” “above,” “upper” and the like, may be used herein for ease of description to describe one element or feature's relationship to other elements or features as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the present disclosure, the terms “about,” “approximately” and “substantially” typically mean +/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. The stated value of the present disclosure is an approximate value. That is, when there is no specific description of the terms “about,” “approximately” and “substantially”, the stated value includes the meaning of “about,” “approximately” or “substantially”.

Unless otherwise defined, all terms (including technical and scientific terms) used herein have the same meaning as commonly understood by one of ordinary skill in the art to which this disclosure belongs. It should be understood that terms such as those defined in commonly used dictionaries should be interpreted as having a meaning that is consistent with their meaning in the context of the relevant art and will not be interpreted in an idealized or overly formal sense unless expressly so defined in the embodiments of the present disclosure.

The present disclosure may repeat reference numerals and/or letters in following embodiments. This repetition is for the purpose of simplicity and clarity and does not in itself dictate a relationship between the various embodiments and/or configurations discussed.

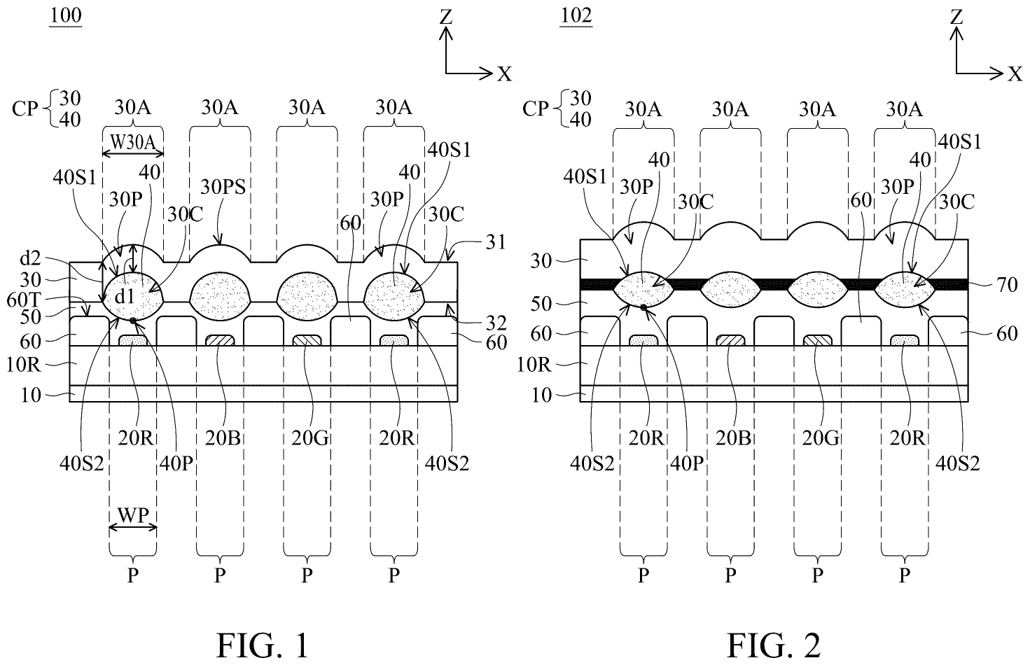

FIG. 1 is a partial cross-sectional view illustrating a display panel 100 according to some embodiments of the present disclosure. It should be noted that, for the sake of brevity, some components of the display panel 100 have been omitted in FIG. 1.

Referring to FIG. 1, in some embodiments, the display panel 100 includes a circuit substrate 10 that defines multiple pixel regions P. For example, the circuit substrate 10 may be a display substrate, a light-emitting substrate, a substrate with functional elements such as thin-film transistors (TFT) or integrated circuits (IC), or any other type of circuit substrate. Moreover, the circuit substrate 10 may be a rigid circuit substrate, which may include an elemental semiconductor (e.g., silicon or germanium), a compound semiconductor (e.g., silicon carbide (SiC), gallium arsenide (GaAs), indium arsenide (InAs), or indium phosphide (InP)), an alloy semiconductor (e.g., SiGe, SiGeC, GaAsP, or GaInP), any other suitable semiconductor, or a combination thereof. Alternatively, the circuit substrate 10 may be a flexible circuit substrate, a semiconductor-on-insulator (SOI) substrate, or any other similar substrate.

The circuit substrate 10 may include various conductive components (e.g., conductive lines or vias). For example, the conductive components may include aluminum (Al), copper (Cu), tungsten (W), an alloy thereof, any other suitable conductive material, or a combination thereof. In the example where the circuit substrate 10 is a display substrate, the circuit substrate 10 may be connected to an external circuit (not shown) to drive and operate light-emitting chips (e.g., micro light-emitting chips 20R, 20G, and 20B).

Referring to FIG. 1, in some embodiments, the display panel 100 includes multiple micro light-emitting chips 20R, 20G, and 20B that are disposed on the circuit substrate 10, and each pixel region P corresponds to at least one of the micro light-emitting chips 20R, 20G, and 20B.

The micro light-emitting chips 20R, 20G, and 20B may be formed by an epitaxial growth process. For example, the epitaxial growth process may include metal-organic chemical vapor deposition (MOCVD), hydride vapor phase epitaxy (HVPE), molecular beam epitaxy (MBE), or any other applicable method, or a combination thereof, but the present disclosure is not limited thereto.

Moreover, each of the micro light-emitting chips 20R, 20G, and 20B may include N-type semiconductor materials, such as group II-VI materials (e.g., zinc selenide (ZnSe)) or group III-V nitrogen compound materials (e.g., gallium nitride (GaN), aluminum nitride (AlN), indium nitride (InN), indium gallium nitride (InGaN), aluminum gallium nitride (AlGaN), or aluminum indium gallium nitride (AlInGaN)). The N-type semiconductor materials may also include dopants such as silicon (Si) or germanium (Ge), but the present disclosure is not limited thereto. The N-type semiconductor materials may be a single-layer or multi-layer structure.

Each of the micro light-emitting chips 20R, 20G, and 20B may also include a light-emitting layer, which may include an undoped semiconductor layer or a lightly doped semiconductor layer. For example, the light-emitting layer may be a quantum well (QW) layer, which may include indium gallium nitride (InₓGa₁₋ₓN) or gallium nitride (GaN), but the present disclosure is not limited thereto. Alternatively, the light-emitting layer may be a multiple quantum well (MQW) layer.

The light emitted from the micro light-emitting chips 20R, 20G, and 20B is determined by the light-emitting layer. For example, the micro light-emitting chip 20R may be a micro red light chip, the micro light-emitting chip 20G may be a micro green light chip, and the micro light-emitting chip 20B may be a micro blue light chip. However, the present disclosure is not limited thereto. Moreover, the display panel 100 may also include micro light-emitting chips that emit other colors of light, such as white, yellow, cyan, magenta, or emerald.

Each of the micro light-emitting chips 20R, 20G, and 20B may further include P-type semiconductor materials, such as group II-VI materials (e.g., zinc selenide (ZnSe)) or group III-V nitrogen compound materials (e.g., gallium nitride (GaN), aluminum nitride (AlN), indium nitride (InN), indium gallium nitride (InGaN), aluminum gallium nitride (AlGaN), or aluminum indium gallium nitride (AlInGaN)). The P-type semiconductor materials may also include dopants such as magnesium (Mg), carbon (C), but the present disclosure is not limited thereto. Moreover, the P-type semiconductor materials may be a single-layer or multi-layer structure.

Referring to FIG. 1, in some embodiments, the display panel 100 includes a refractive layer 30 that covers the pixel regions P and has a first refractive index. For example, the refractive layer 30 may be made of glass, and the first refractive index is about 1.5, but the present disclosure is not limited thereto. The refractive layer 30 is divided into multiple refractive regions 30A that correspond to the pixel regions P, and there are multiple protrusions 30P on the first side 31 of the refractive layer 30 away from the circuit substrate 10.

Referring to FIG. 1, in some embodiments, the display panel 100 includes a refraction structure 40 that is disposed on the second side 32 of the refractive layer 30 facing the circuit substrate 10 (i.e., opposite the first side 31) and has a second refractive index. The second refractive index of the refraction structure 40 is different from the first refractive index of the refractive layer 30. The refractive layer 30 and the refraction structure 40 together may be regarded as a cover plate structure CP of the display panel 100. As shown in FIG. 1, in this embodiment, the cover plate structure CP includes multiple refraction structures 40 that correspond to the protrusions 30P on the refractive layer 30 to define the refractive regions 30A.

The refraction structure 40 may include glass, epoxy resin, silicone resin, polyurethane, any other suitable material, or a combination thereof, but the present disclosure is not limited thereto. For example, the refraction structure 40 may be formed by photoresist reflow, hot embossing, any other suitable method, or a combination thereof. The steps for forming the refraction structure 40 may include spin coating, photolithography, etching, any other suitable process, or a combination thereof, but the present disclosure is not limited thereto.

In this embodiment, the second refractive index of the refraction structure 40 is greater than the first refractive index of the refractive layer 30, and each refraction structure 40 is a biconvex lens. For example, the second refractive index of the refraction structure 40 is greater than about 1.5 and less than about 2.0, but the present disclosure is not limited thereto. Moreover, as shown in FIG. 1, the second side 32 of the refractive layer 30 includes multiple recesses 30C, and at least a portion of each refraction structure 40 is disposed in a corresponding recess 30C. In the cross-sectional view shown in FIG. 1, the refraction structure 40 has a curved surface 40S1 disposed in the corresponding recess 30C and a curved surface 40S2 protruding from the corresponding recess 30C.

In some embodiments, in a cross-sectional view (e.g., as shown in FIG. 1), the curved surface 40S1 and the surface 30PS of the corresponding protrusion 30P define the thickness of the refractive layer 30 in the vertical direction (e.g., the Z direction in FIG. 1), and the thickness varies along the horizontal direction (e.g., the X direction in FIG. 1). For example, the distance d1 between the center of the curved surface 40S1 and the surface 30PS of the corresponding protrusion 30P in the Z direction is shorter than the distance d2 between the edge of the curved surface 40S1 and the surface 30PS of the corresponding protrusion 30P in the Z direction. As shown in FIG. 1, due to the difference between distances d1 and d2, the radius of curvature of the curved surface 40S1 is smaller than the radius of curvature of the curved surface 40S2. When the radius of curvature of the curved surface 40S2 is larger, the incident angle of light reaching the same surface position of the refraction structure 40 decreases, reducing the divergence angle of light within the refraction structure 40. On the other hand, when light continues to enter the curved surface 40S1, it enters the refractive layer 30, which has a smaller refractive index, and particularly for light with larger divergence angles, the smaller radius of curvature of the curved surface 40S1 may amplify the incident angle of light, enhancing the convergence of light towards the center of the optical axis.

Moreover, the curved surface 40S2 of the refraction structure 40 is relatively flat, offering advantages in both processing and optics. For example, the refraction structure 40 may be disposed closer to the micro light-emitting chips 20R, 20G, and 20B, allowing the refraction structure 40 to receive light at a larger incident angle. Consequently, the width W30A of each refraction structure 40 may be reduced, so that the space between the refraction structures 40 may be increased, allowing for more misalignment tolerance during the manufacturing process. Furthermore, as the distance between the refraction structure 40 and the micro light-emitting chips 20R, 20G, and 20B is reduced, the distribution of light received by the surface of the refraction structure 40 changes. Specifically, a wider range of light angles may be received near the center of the refraction structure 40, especially for light with larger original divergence angles, where the average incident angle decreases significantly.

Referring to FIG. 1, in some embodiments, the display panel 100 includes a light-transmitting layer 50 that is disposed between the refractive layer 30 and the circuit substrate 10 and covers the micro light-emitting chips 20R, 20G, and 20B. The light-transmitting layer 50 has a third refractive index, and the third refractive index of the light-transmitting layer 50 is lower than the second refractive index of the refraction structure 40. For example, the light-transmitting layer 50 may be an optical clear resin (OCR) with a third refractive index of about 1.5, but the present disclosure is not limited thereto. The light-transmitting layer 50 may be used in a full-lamination process to improve the overall optical performance of the display panel 100.

As shown in FIG. 1, in this embodiment, a biconvex refraction structure 40 with a refractive index higher than about 1.5 is placed between the refractive layer 30 and the light-transmitting layer 50, both of which have refractive indices of about 1.5. This design allows light, originally divergent from the periphery, to be refocused and directed towards the center, increasing the forward-emitted light from the micro light-emitting chips (e.g., micro light-emitting chips 20R, 20G, or 20B). Here, the refraction structure 40 primarily collects light with larger divergence angles. This light is refracted a second time, with most of which converging along the central axis of the micro light-emitting chips (e.g., micro light-emitting chips 20R, 20G, or 20B), while only a small portion (e.g., light with an originally small divergence angle) will slightly diverge beyond the central axis of the micro light-emitting chips (e.g., micro light-emitting chips 20R, 20G, or 20B). However, since the initial incident angle when the light enters the curved surface 40S2 is very small, the second incident angle (from curved surface 40S1 into protrusion 30P) forms a very small angle with the central axis of the micro light-emitting chips (e.g., micro light-emitting chips 20R, 20G, or 20B). In other words, the divergence effect caused by the second refraction is almost negligible.

In some embodiments, in a cross-sectional view (e.g., as shown in FIG. 1), the refractive layer 30 forms a concave-convex lens in each refractive region 30A. Designing the interface between air, with a refractive index of about 1.0, and the refractive layer 30, with a refractive index of about 1.5, as a concave-convex glass structure, compared to a flat glass surface, may may deflect the normal of the incident angle to the surface of the refractive layer 30, bending the light from the outside of the incident point toward the inside. This allows the previously diverged light to be redirected toward the central axis of the micro light-emitting chips (e.g., micro light-emitting chips 20R, 20G, or 20B). At the same time, the refractive layer 30 is designed to complement the refractive effect of the refraction structure 40, and the refractive index gradient between the refraction structure 40 and the air may be reduced due to the refractive index of the refractive layer 30, thereby lowering the chances of total internal reflection.

Referring to FIG. 1, in some embodiments, the display panel 100 includes an array structure 60 that is disposed on the circuit substrate 10 and separates the pixel regions P. Specifically, the array structure 60 may be disposed between the micro light-emitting chip 20R and the micro light-emitting chip 20B, between the micro light-emitting chip 20B and the micro light-emitting chip 20G, and/or between the micro light-emitting chip 20G and the micro light-emitting chip 20R. For example, the array structure 60 may include metals such as nickel, silver, platinum, or the array structure 60 may include (white) resin, but the present disclosure is not limited thereto. The array structure 60 may be formed by physical vapor deposition (PVD), chemical vapor deposition (CVD), atomic layer deposition (ALD), evaporation, sputtering, any similar process, or a combination thereof, but the present disclosure is not limited thereto.

As shown in FIG. 1, in some embodiments, in a direction parallel to the circuit substrate 10 (e.g., the X direction in FIG. 1), the width WP of each pixel region is smaller than the width W30A of each refractive region 30A, allowing the refraction structure 40 to collect as much light emitted by the micro light-emitting chips 20R, 20G, and 20B as possible.

As shown in FIG. 1, the array structure 60 has a top surface 60T, and in at least one refractive region 30A, the curved surface 40S2 of the refraction structure 40, which is away from the refractive layer 30, has an apex 40P. The apex 40P is at the same height as the top surface 60T in the vertical direction relative to the circuit substrate 10 (e.g., the Z direction in FIG. 1), or the apex 40P between the top surface 60T and the circuit substrate 10. In some embodiments, the display panel 100 includes a reflective layer 10R that is disposed between the circuit substrate 10 and the micro light-emitting chips 20R, 20G, and 20B, which may further reflect the light emitted by the micro light-emitting chips 20R, 20G, and 20B, thereby increasing the forward-emitted light from the micro light-emitting chips 20R, 20G, and 20B.

It should be noted that, although FIG. 1 illustrates the reflective layer 10R between the circuit substrate 10 and the micro light-emitting chips 20R, 20G, and 20B, the micro light-emitting chips 20R, 20G, and 20B are still electrically connected to the circuit substrate 10. For example, the reflective layer 10R may include reflective materials that are the same as or similar to the array structure 60, which may be a non-rigid film layer made by spin coating and used to reflect light from the bottom. When the display panel 100 is used for a transparent display, the display panel 100 may not include the reflective layer 10R.

FIG. 2 to FIG. 5 are partial cross-sectional views respectively illustrating the display panels 102, 104, 106, and 108 according to some other embodiments of the present disclosure. It should be noted that some components of the display panels 102, 104, 106, and 108 are omitted in FIG. 2 to FIG. 5 for the sake of brevity.

Referring to FIG. 2, in this embodiment, the display panel 102 further includes a light-shielding layer 70 that is disposed on the micro light-emitting chips 20R, 20G, and 20B and surrounds the refraction structure 40. For example, the light-shielding layer 70 may include a photoresist (e.g., black photoresist or any other suitable opaque photoresist), ink (e.g., black ink or any other suitable opaque ink), a molding compound (e.g., black molding compound or any other suitable opaque molding compound), a solder mask (e.g., black solder mask or any other suitable opaque solder mask), an epoxy resin, any other suitable material, or a combination thereof. Moreover, the light-shielding layer 70 may be a photo-curable material, a heat-curable material, or a combination thereof, but the present disclosure is not limited thereto.

The light-shielding layer 70 may be formed by physical vapor deposition (PVD), chemical vapor deposition (CVD), atomic layer deposition (ALD), evaporation, sputtering, any other similar process, or a combination thereof, but the present disclosure is not limited thereto. The light-shielding layer 70 may be used to reduce crosstalk between the light emitted by the micro light-emitting chips 20R, 20G, and 20B.

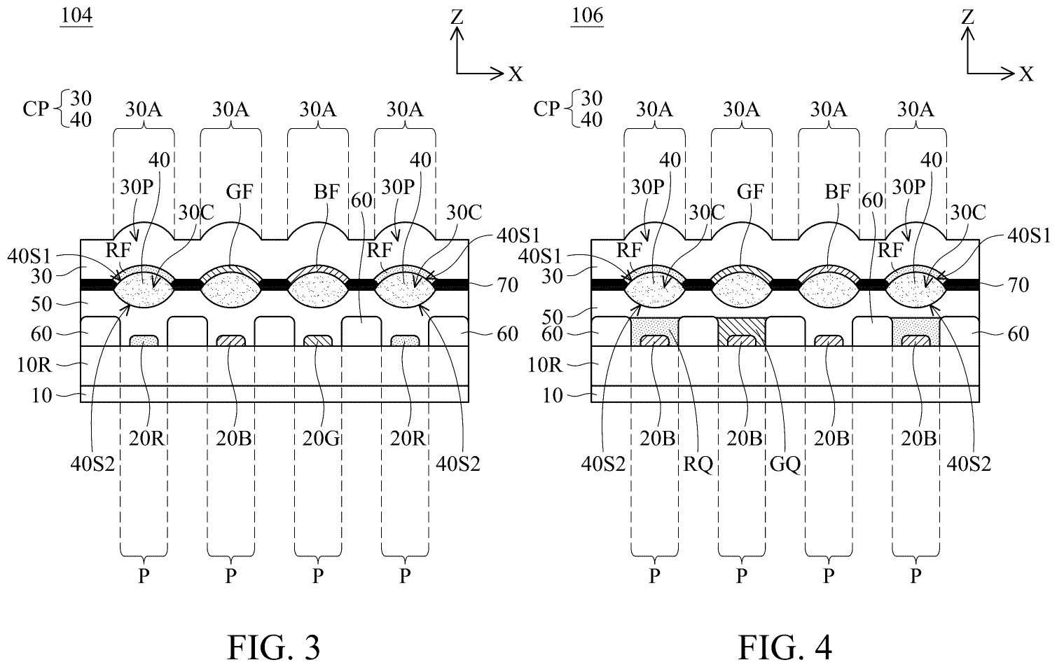

Referring to FIG. 3, in this embodiment, the display panel 104 further includes filter layers (RF, GF, BF) that are disposed between the refractive layer 30 and the refraction structure 40. For example, the filter layer RF is a red filter structure corresponding to the micro light-emitting chip 20R (e.g., disposed over the micro light-emitting chip 20R) and may block most non-red light from passing through; the filter layer GF is a green filter structure corresponding to the micro light-emitting chip 20G (e.g., disposed over the micro light-emitting chip 20G) and may block most non-green light from passing through; the filter layer BF is a blue filter structure corresponding to the micro light-emitting chip 20B (e.g., disposed over the micro light-emitting chip 20B) and may block most non-blue light from passing through. The filter layers RF, GF, and BF may further improve the color saturation of the display panel 104.

Referring to FIG. 4, in this embodiment, the display panel 106 includes micro light-emitting chips 20B but does not include micro light-emitting chips 20R and 20G. Moreover, the display panel 106 further includes multiple light conversion structures RQ and GQ that are disposed on some light-emitting chips 20B that emit blue light to convert the wavelength of the light emitted by the micro light-emitting chips 20B. For example, the light conversion structure RQ may include red quantum dot material, which may be excited by the blue light emitted by the micro light-emitting chips 20B and emit red light, forming red subpixels; the light conversion structure GQ may include green quantum dot material, which may be excited by the blue light emitted by the micro light-emitting chips 20B and emit green light, forming green subpixels; the blue lights emitted by the micro light-emitting chips 20B that are not converted by any light conversion structure may form blue subpixels, but the present disclosure is not limited thereto. The red, green, and blue subpixels may combine to form a pixel, and multiple pixels are arranged in an array in the display panel 106 to display images.

Similarly, the display panel 106 may also include filter layers (e.g., filter layers RF, GF, BF) that are disposed between the refractive layer 30 and the refraction structure 40, and will not be repeated here. In the display panel 106, the filter layer RF corresponds to the micro light-emitting chip 20B and the light conversion structure RQ, while the filter layer GF corresponds to the micro light-emitting chip 20B and the light conversion structure GQ. For a display panel 106 using light conversion structures RQ and GQ, the filter layer helps prevent light crosstalk between pixels. In more detail, since the conversion efficiency of the quantum dot material cannot reach 100%, unconverted lights will be partially reflected by the filter layer at curved surface 40S1, and the reflected lights may largely pass beyond the central axis of the micro light-emitting chip and be refracted by curved surface 40S2 as stray lights. Moreover, the stray lights may further interfere with surrounding subpixels via reflection from the reflective material on the array structure 60. The filter layer ensures that the display panel 106 only benefits from the increased forward light output provided by the refraction structure 40, while preventing the adverse effects that the refraction structure 40 may generate.

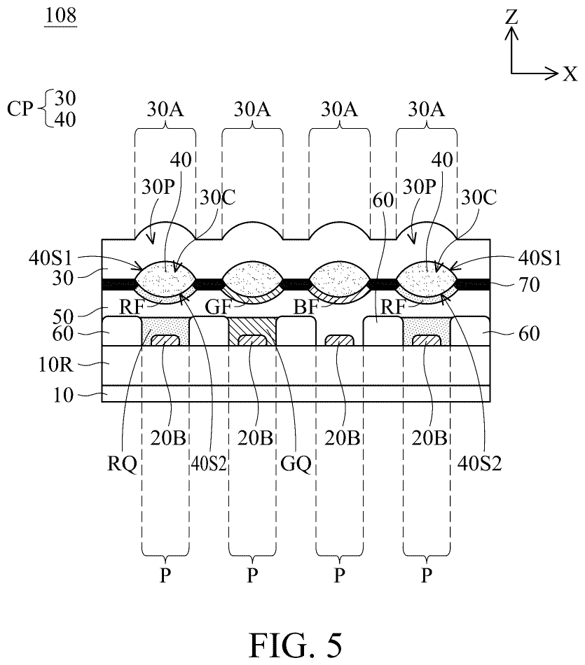

Referring to FIG. 5, the main difference between the display panel 108 in this embodiment and the display panel 106 shown in FIG. 4 is that the filter layer (e.g., filter layers RF, GF, BF) is disposed on the curved surface 40S2 of the refraction structure 40 away from the refractive layer 30. Similarly, since the conversion efficiency of the quantum dot material cannot reach 100%, unconverted lights will be partially reflected by the filter layer at curved surface 40S2, and the reflected lights may largely pass beyond the central axis of the micro light-emitting chip. The stray lights may further interfere with surrounding subpixels via reflection from the reflective material on the array structure 60. The filter layer ensures that the display panel 108 only benefits from the increased forward light output provided by the refraction structure 40, while preventing the adverse effects that the refraction structure 40 may generate. Compared to the embodiment where the filter layer (RF, GF, BF) is disposed on the curved surface 40S1 of the refraction structure 40 near the refractive layer 30 (e.g., the display panel 106 shown in FIG. 4), in this embodiment, the filter layer (RF, GF, BF) is disposed closer to the micro light-emitting chip 20B, allowing more lights to be received. Moreover, only light that passes through the filter layer (RF, GF, BF) will be refracted, meaning the refraction structure 40 will not refract any unconverted, ineffective light.

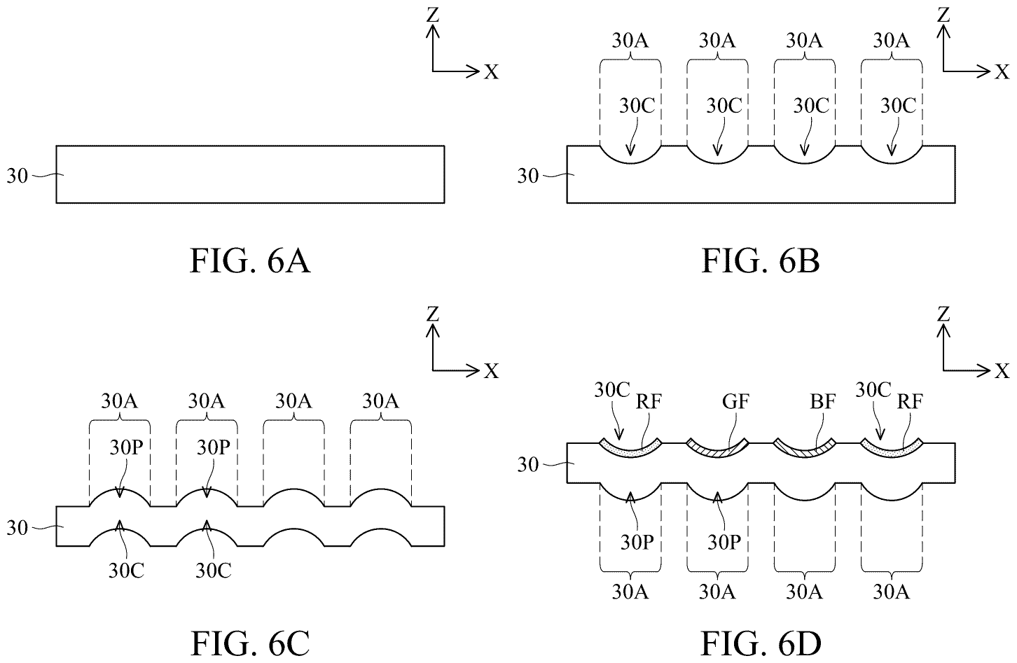

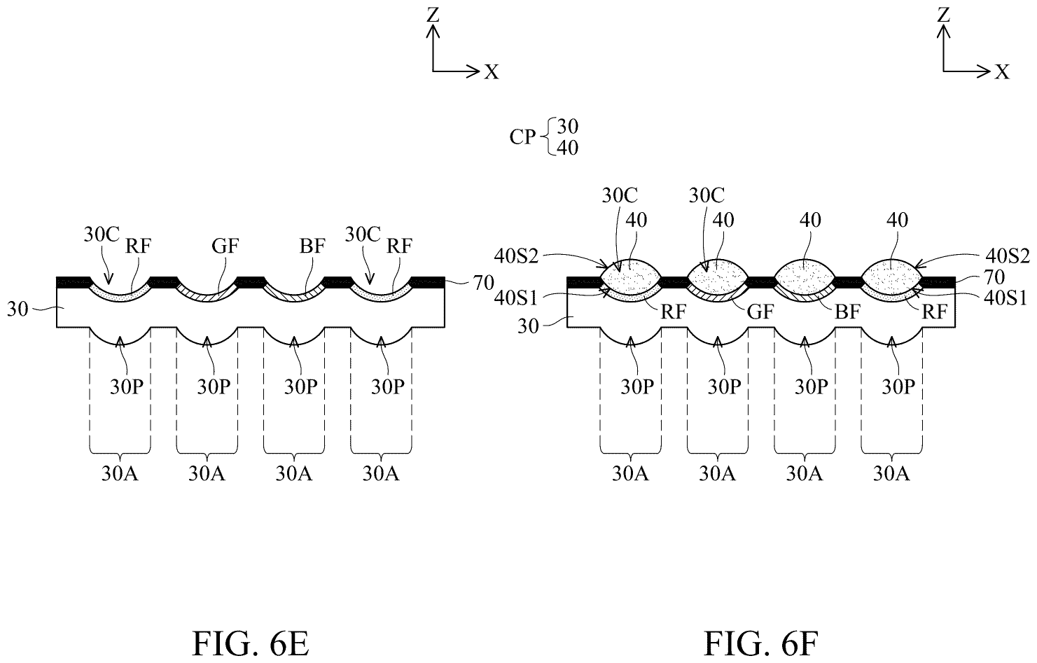

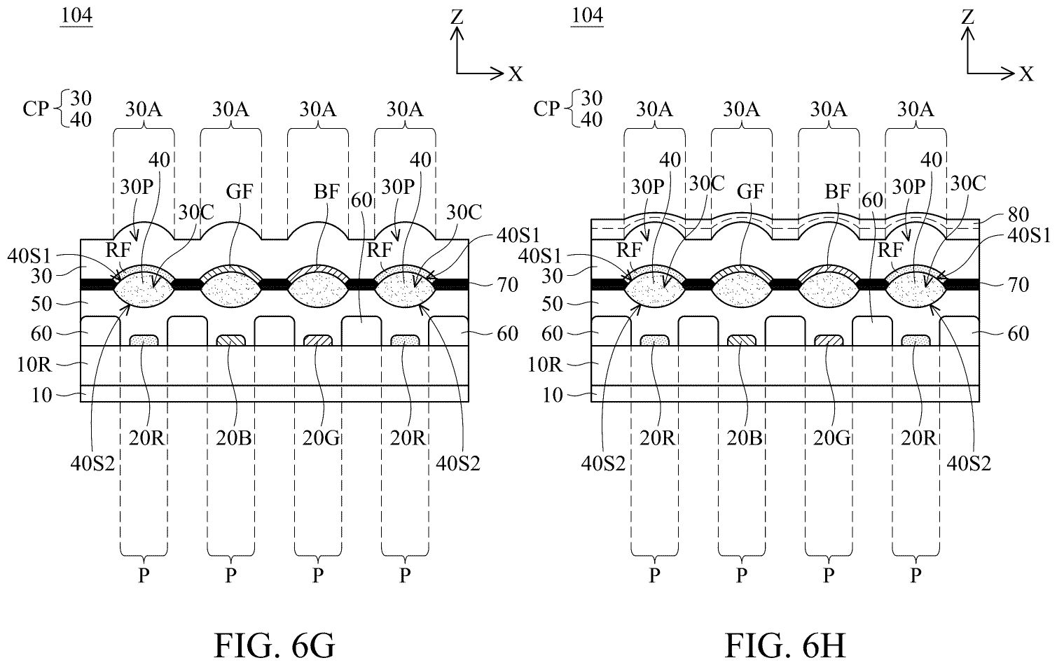

FIG. 6A to FIG. 6H are partial cross-sectional views illustrating the method of forming the display panel 104 at various stages according to some embodiments of the present disclosure. It should be noted that some components of the display panel 104 are omitted in FIG. 6A to FIG. 6H for the sake of brevity.

First, as shown in FIG. 6A, a refractive layer 30 is provided. Then, as shown in FIG. 6B, the refractive layer 30 is patterned to form at least one recess 30C, and the recess 30C is defined as the refractive region 30A on the refractive layer 30. The recess 30C may be formed by forming a mask layer (not shown) over the refractive layer 30, then using the mask layer as an etching mask to etch the shape of the recess 30C into the refractive layer 30.

For example, the mask layer may include photoresist, such as positive photoresist or negative photoresist. The mask layer may include a hard mask and may be formed from silicon dioxide (SiO₂), silicon nitride (SiN), silicon oxynitride (SiON), silicon carbide (SiC), silicon carbon nitride (SiCN), any similar material, or a combination thereof, but the present disclosure is not limited thereto. The mask layer may be a single-layer or multi-layer structure. The formation of the mask layer may include a deposition process, a photolithography process, any other suitable process, or a combination thereof, but the present disclosure is not limited thereto. The deposition process may include spin-on coating, chemical vapor deposition, atomic layer deposition, any similar process, or a combination thereof. For example, the photolithography process may include photoresist coating (e.g., spin coating), soft baking, mask aligning, exposure, post-exposure baking (PEB), developing, rinsing, drying (e.g., hard baking), any other suitable process, or a combination thereof, but the present disclosure is not limited thereto.

The etching process may include dry etching, wet etching, or a combination thereof. For example, the dry etching process may include reactive ion etching (RIE), inductively-coupled plasma (ICP) etching, neutral beam etching (NBE), electron cyclotron resonance (ECR) etching, any similar etching process, or a combination thereof, but the present disclosure is not limited thereto. For example, the wet etching process may use etchants such as hydrofluoric acid (HF), ammonium hydroxide (NH₄OH), or any suitable etching agent.

Then, as shown in FIG. 6C, in some embodiments, the refractive layer 30 is flipped and patterned again to form at least one protrusion 30P that corresponds to the recess 30C. The steps of the patterning process are as described previously and will not be repeated here. Then, as shown in FIG. 6D, in some embodiments, filter layers RF, GF, and BF are formed in the recesses 30C. For example, a deposition process may be performed to form the filter layers RF, GF, and BF. Then, as shown in FIG. 6E, in some embodiments, a light-shielding layer 70 is formed on the refractive layer 30, and the light-shielding layer 70 may be between the filter layers RF, GF, and BF. For example, a deposition process may be performed to form the light-shielding layer 70. The examples of the deposition process are as described previously and will not be repeated here.

Then, as shown in FIG. 6F, in some embodiments, a refraction structure 40 is formed on the filter layers RF, GF, and BF to form the cover plate structure CP. In this embodiment, the refraction structure 40 is a biconvex lens, and at least a portion of the refraction structure 40 is disposed in the recess 30C. In cross-sectional view, the refraction structure 40 has a curved surface 40S1 disposed in the corresponding recess 30C and a curved surface 40S2 protruding from the corresponding recess 30C, but the present disclosure is not limited thereto. For example, the refraction structure 40 may be formed by a polymer spray coating process, utilizing the cohesion and surface tension of high-dielectric-constant materials to form the refraction structure 40 in the recess 30C of the refractive layer 30. Alternatively, the refraction structure 40 (e.g., a convex lens) may be automatically formed in the recess 30C by thermal flow of high-dielectric-constant materials after a photolithography process and subsequent heating of the remaining materials in the recess 30C of the refractive layer 30.

It should also be noted that, as shown in FIG. 5 for the display panel 108, the process order of FIG. 6D and FIG. 6F may be reversed. That is, the refraction structure 40 may be formed first, and then the filter layers RF, GF, and BF corresponding to each refractive region 30A may be patterned, thus forming the cover plate structure CP for the display panel 108. Similarly, since the light-shielding layer 70 in FIG. 6E may also be formed using a patterning process, the embodiments of the disclosure do not limit the process order of forming the light-shielding layer 70.

Then, as shown in FIG. 6G, in some embodiments, the cover plate structure CP covers the circuit substrate 10 to form the display panel 104. In more detail, the circuit substrate 10 defines multiple pixel regions P, and the display panel 104 includes multiple micro light-emitting chips 20R, 20G, and 20B that are disposed on the circuit substrate 10, and each pixel region P corresponds to at least one of the micro light-emitting chips 20R, 20G, and 20B. The refractive layer 30 covers the pixel regions P and has a first refractive index, and the refractive regions 30A of the refractive layer 30 corresponds to the pixel regions P.

As shown in FIG. 6H, in some embodiments, the display panel 104 further includes at least one flat layer 80 that is disposed on the protrusions 30P of the refractive layer 30 (corresponding to the first side 31 in FIG. 1). The flatness of the surface of the flat layer 80 is lower than the flatness of the surface of the protrusions 30P. That is, the flat layer 80 has a surface flatter than that of the protrusions 30P. In some embodiments, the refractive index of the flat layer 80 (e.g., about 1.2 to 1.4) is between the refractive index of air (e.g., about 1.0) and the first refractive index of the refractive layer 30 (e.g., about 1.5), which may further reduce the refractive index gradient.

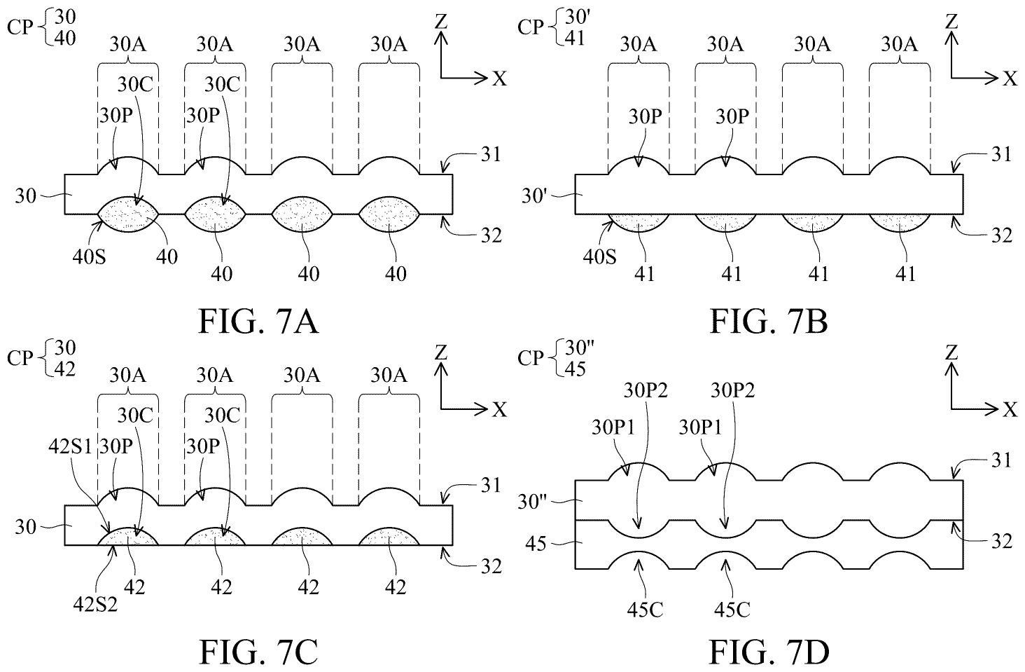

FIG. 7A to FIG. 7D are partial cross-sectional views illustrating the cover plate structure CP according to some embodiments of the present disclosure. As shown in FIG. 7A, in this embodiment, there are multiple protrusions 30P on the first side 31 of the refractive layer 30. Multiple refraction structures 40 are disposed on the second side 32 of the refractive layer 30, each refraction structure is a biconvex lens, and the (second) refractive index of the refraction structures 40 is greater than the (first) refractive index of the refractive layer 30. Furthermore, in this embodiment, there are multiple recesses 30C on the second side 32 of the refractive layer 30 that correspond to the protrusions 30P, and at least a portion of each refraction structure 40 is disposed in a corresponding recess 30C.

As shown in FIG. 7B, in this embodiment, there are multiple protrusions 30P on the first side 31 of the refractive layer 30′. Multiple refraction structures 41 are disposed on the second side 32 of the refractive layer 30′, each refraction structure 41 is a plane-convex lens, and the (second) refractive index of the refraction structures 41 is greater than the (first) refractive index of the refractive layer 30′. Furthermore, in this embodiment, the second side 32 of the refractive layer 30′ has a flat surface, and the refraction structures 41 protrude from this flat surface.

As shown in FIG. 7C, in this embodiment, there are multiple protrusions 30P on the first side 31 of the refractive layer 30. Multiple refraction structures 42 are disposed on the second side 32 of the refractive layer 30, each refraction structure 42 is a plane-convex lens, and the (second) refractive index of the refraction structures 42 is greater than the (first) refractive index of the refractive layer 30. Furthermore, in this embodiment, there are multiple recesses 30C on the second side 32 of the refractive layer 30 that correspond to the protrusions 30P, and the refraction structures 42 are entirely disposed in the recesses 30C. The refraction structures 42 have multiple second surfaces 42S2 on the opposite side of the curved surface 42S1, which are aligned with the refractive layer 30 and form a flat surface with the second side 32 of the refractive layer 30.

As shown in FIG. 7D, in this embodiment, there are multiple protrusions 30P1 on the first side 31 of the refractive layer 30″, and there are multiple protrusions 30P2 on the second side 32 of the refractive layer 30″. Refraction structures 45 are disposed on the second side 32 of the refractive layer 30″, and the (second) refractive index of the refraction structures 45 is less than the (first) refractive index of the refractive layer 30″. Furthermore, in this embodiment, the refraction structures 45 have multiple recesses 45C on the side away from the refractive layer 30″, and the recesses 45C correspond to the protrusions 30P1 and 30P2 of the refractive layer 30″.

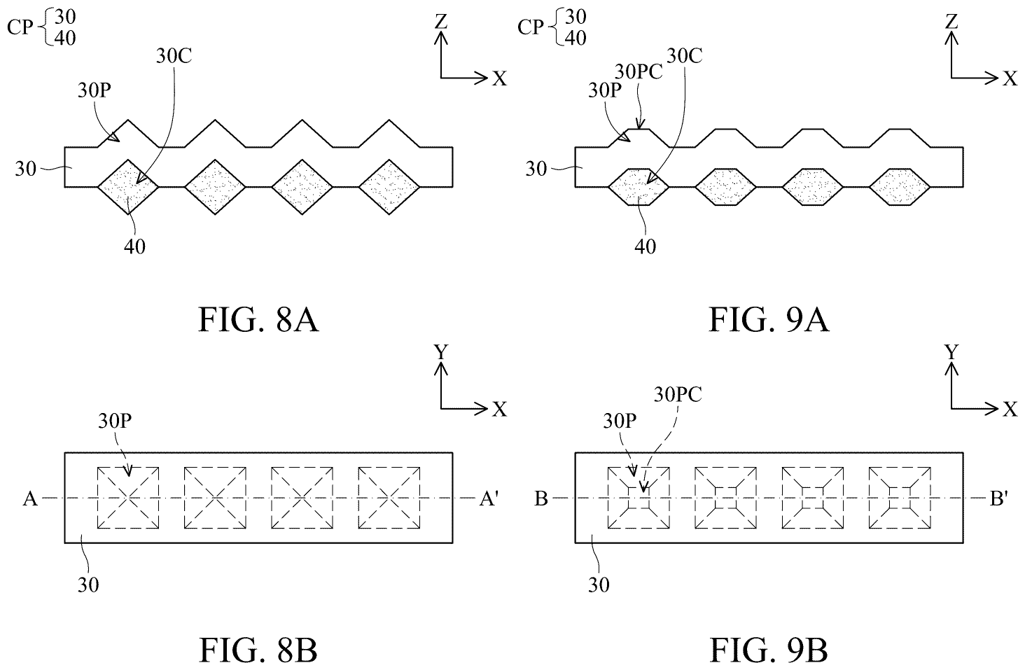

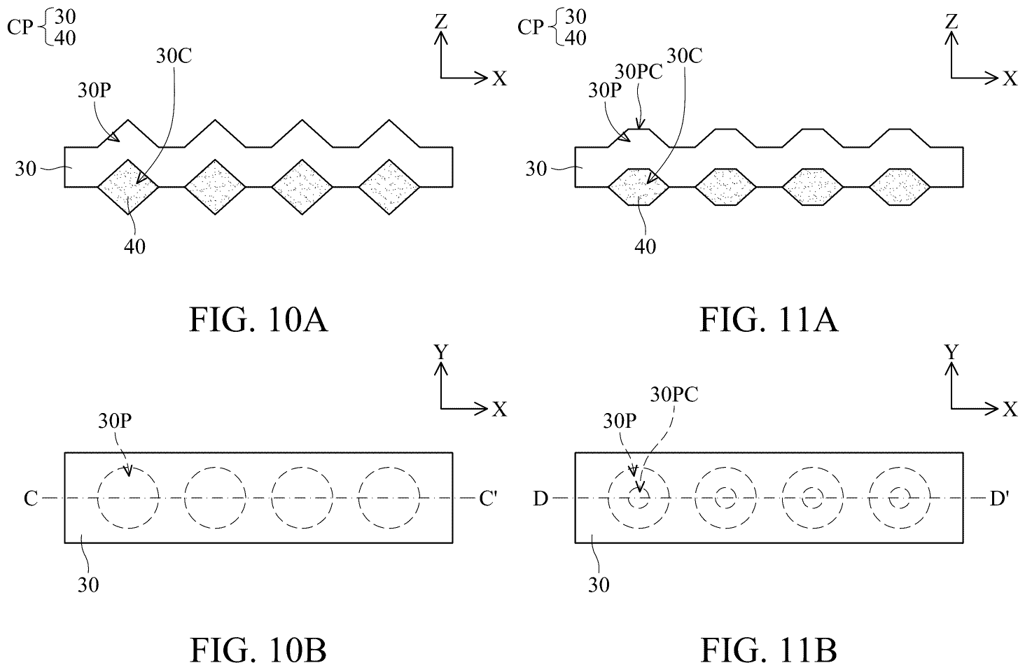

FIG. 8A and FIG. 9A are partial cross-sectional views illustrating the cover plate structure CP according to some other embodiments of the present disclosure. FIG. 8B and FIG. 9B are partial top views illustrating the cover plate structure CP according to some other embodiments of the present disclosure. For example, FIG. 8A is a partial cross-sectional view of the cover plate structure CP along line A-A′ in FIG. 8B, and FIG. 9A is a partial cross-sectional view of the cover plate structure CP along line B-B′ in FIG. 9B.

As shown in FIG. 8A and FIG. 8B, in this embodiment, the protrusion 30P of the refractive layer 30 is a polygonal pyramid (e.g., quadrilateral pyramid). Furthermore, the refractive layer 30 has multiple recesses 30C that correspond to the protrusions 30P, and at least a portion of each refraction structure 40 is disposed in a corresponding recess 30C. Therefore, the refraction structure 40 may also be a polygonal pyramid (e.g., octagonal pyramid), but the present disclosure is not limited thereto.

As shown in FIG. 9A and FIG. 9B, in this embodiment, the protrusion 30P of the refractive layer 30 is a polygonal pyramid (e.g., quadrilateral pyramid) that has a top platform 30PC. Furthermore, the refractive layer 30 has multiple recesses 30C that correspond to the protrusions 30P, and at least a portion of each refraction structure 40 is disposed in a corresponding recess 30C. Therefore, the refraction structure 40 may also be a polygonal pyramid (e.g., octagonal pyramid) that has a top platforms 30PC, but the present disclosure is not limited thereto.

FIG. 10A and FIG. 11A are partial cross-sectional views illustrating the cover plate structure CP according to some other embodiments of the present disclosure. FIG. 10B and FIG. 11B are partial top views illustrating the cover plate structure CP according to some other embodiments of the present disclosure. For example, FIG. 10A is a partial cross-sectional view of the cover plate structure CP along line C-C′ in FIG. 10B, and FIG. 11A is a partial cross-sectional view of the cover plate structure CP along line D-D′ in FIG. 11B.

As shown in FIG. 10A and FIG. 10B, in this embodiment, the protrusion 30P of the refractive layer 30 is a cone. Furthermore, the refractive layer 30 has multiple recesses 30C that correspond to the protrusions 30P, and at least a portion of each refraction structure 40 is disposed in a corresponding recess 30C. Therefore, the refraction structure 40 may also be a cone, but the present disclosure is not limited thereto.

As shown in FIG. 11A and FIG. 11B, in this embodiment, the protrusion 30P of the refractive layer 30 is a cone that has a top platform 30PC. Furthermore, the refractive layer 30 has multiple recesses 30C that correspond to the protrusions 30P, and at least a portion of each refraction structure 40 is disposed in a corresponding recess 30C. Therefore, the refraction structures 40 may also be a cone that has a top platform 30PC, but the present disclosure is not limited thereto.

As noted above, the cover plate structure according to the embodiments of the disclosure includes a refractive layer and at least one refraction structure, which may change the direction of the light passing through, thereby increasing the overall brightness in the forward direction (e.g., the emission surface of the light-emitting chip or the normal direction facing the viewer). Moreover, the cover plate structure may effectively reduce light mixing, thus improving the overall display quality.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. Therefore, the scope of protection should be determined through the claims. In addition, although some embodiments of the present disclosure are disclosed above, they are not intended to limit the scope of the present disclosure.

Reference throughout this specification to features, advantages, or similar language does not imply that all of the features and advantages that may be realized with the present disclosure should be or are in any single embodiment of the disclosure. Rather, language referring to the features and advantages is understood to mean that a specific feature, advantage, or characteristic described in connection with an embodiment is included in at least one embodiment of the present disclosure. Thus, discussions of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the relevant art will recognize, in light of the description herein, that the disclosure can be practiced without one or more of the specific features or advantages of a particular embodiment. In other instances, additional features and advantages may be recognized in certain embodiments that may not be present in all embodiments of the disclosure.

What is claimed is:

1. A cover plate structure, comprising:
a refractive layer having a first refractive index and divided into refractive regions, wherein there are first protrusions on a first side of the refractive layer, and each of the refractive regions corresponds to one of the first protrusions; and
at least one refraction structure disposed on a second side of the refractive layer and having a second refractive index, wherein the second side is opposite the first side, and the second refractive index is different from the first refractive index.

2. The cover plate structure as claimed in claim 1, wherein the second refractive index is greater than the first refractive index, and each of the refraction structures is a plane-convex lens or a biconvex lens.

3. The cover plate structure as claimed in claim 1, wherein the cover plate structure comprises refraction structures, and the second side of the refractive layer has recesses, at least a portion of each of the refraction structures is disposed in one of the recesses, and in a cross-sectional view, each of the refraction structures has a first curved surface disposed in a corresponding one of the recesses.

4. The cover plate structure as claimed in claim 3, wherein each of the refraction structures is a biconvex lens, and in the cross-sectional view, each of the refraction structures also has a second curved surface protruding from the corresponding one of the recesses, the second curved surface is disposed on the opposite side of the refraction structure relative to the first curved surface, and a radius of curvature of the first curved surface is smaller than a radius of curvature of the second curved surface.

5. The cover plate structure as claimed in claim 3, wherein in the cross-sectional view, the first curved surface and a surface of a corresponding one of the first protrusions define a thickness of the refractive layer in a vertical direction, and the thickness varies along a horizontal direction.

6. The cover plate structure as claimed in claim 3, wherein in the cross-sectional view, the refractive layer forms a concave-convex lens in each of the refractive regions.

7. The cover plate structure as claimed in claim 3, wherein the refraction structures are completely disposed in the recesses, and on a side opposite the first curved surfaces, there are surfaces aligned with the refractive layer, and the surfaces and the second side of the refractive layer construct a flat surface.

8. The cover plate structure as claimed in claim 1, wherein the second side of the refractive layer has a flat surface, and the refraction structure protrudes from the flat surface.

9. The cover plate structure as claimed in claim 1, wherein there are second protrusions on the second side of the refractive layer, the second protrusions correspond to the first protrusions, and the second refractive index is smaller than the first refractive index.

10. The cover plate structure as claimed in claim 9, wherein the refraction structure has recesses on a side away from the refractive layer, and the recesses correspond to the first protrusions and the second protrusions.

11. The cover plate structure as claimed in claim 1, wherein each of the first protrusions is a polygonal pyramid or a cone, or each of the first protrusions is a polygonal pyramid or a cone that has a top platform.

12. A display panel, comprising:
a circuit substrate defining pixel regions;
micro light-emitting chips disposed on the circuit substrate, wherein each of the pixel regions corresponds to at least one of the micro light-emitting chips;
a refractive layer covering the pixel regions and having a first refractive index, wherein the refractive layer is divided into refractive regions that correspond to the pixel regions, and there are first protrusions on a first side of the refractive layer that is away from the circuit substrate, and each of the refractive regions corresponds to one of the first protrusions; and
at least one refraction structure disposed on a second side of the refractive layer facing the circuit substrate and having a second refractive index, wherein the second refractive index is different from the first refractive index.

13. The display panel as claimed in claim 12, further comprising:
a light-transmitting layer disposed between the refractive layer and the circuit substrate and covering the micro light-emitting chips.

14. The display panel as claimed in claim 13, wherein the light-transmitting layer has a third refractive index, and the third refractive index is lower than the second refractive index.

15. The display panel as claimed in claim 12, further comprising:
at least one flat layer disposed on the first side of the refractive layer, and a flatness of a surface of the flat layer is lower than a flatness of a surface of the first protrusions.

16. The display panel as claimed in claim 15, wherein a refractive index of the flat layer is between a refractive index of air and the first refractive index.

17. The display panel as claimed in claim 12, further comprising:
a filter layer disposed between the refractive layer and the refraction structures or disposed on a surface of the refraction structures away from the refractive layer.

18. The display panel as claimed in claim 12, further comprising:
an array structure disposed on the circuit substrate and dividing the pixel regions, wherein in a direction parallel to the circuit substrate, a width of each of the pixel regions is smaller than a width of each of the refractive regions.

19. The display panel as claimed in claim 18, wherein the array structure has a top surface, and in at least one of the refractive regions, the refraction structure has a vertex on a surface away from the refractive layer, and the vertex is level with the top surface or disposed between the top surface and the circuit substrate in a direction perpendicular to the circuit substrate.
